(19) United States
(12) Patent Application Publication
(10) Pub. No.: US 2020/0006034 A1
(43) Pub. Date: Jan. 2, 2020

(54) CHARACTERIZATION OF REGIONS WITH DIFFERENT CRYSTALLINITY IN MATERIALS

(71) Applicant: IMEC vzw, Leuven (BE)

(72) Inventors: Andreas Schulze, Heverlee (BE); Wilfried Vandervorst, Mechelen (BE)

(21) Appl. No.: 16/455,528

(22) Filed: Jun. 27, 2019

Related U.S. Application Data
(63) Continuation of application No. PCT/EP2017/083186, filed on Dec. 18, 2017.

(30) Foreign Application Priority Data
Dec. 30, 2016 (EP) 16207649.1

(51) Int. Cl. H01J 37/244

(52) U.S. Cl. CPC H01J 37/244; H01J 2237/22; H01J 2237/24475

(57) ABSTRACT

A method of characterizing a region in a sample under study, and related systems, is disclosed. In once aspect, the sample under study comprises a first region having first crystalline properties and a second region having second crystalline properties. The method comprises irradiating the sample under study with an electron beam, the average relative angle between the electron beam and the sample under study being selected so that a contribution in the backscattered or forward scattered signal of the first region is distinguishable from that of the second region. The method further comprises detecting the backscattered or forward scattered electrons, and deriving a characteristic of the first and/or the second region from the detected backscattered or forward scattered electrons. The instantaneous relative angle between the electron beam and the sample under study is modulated with a predetermined modulation frequency during the irradiating the sample under study with an electron beam. Detecting the backscattered or forward scattered electrons is performed at the predetermined modulation frequency.

### CROSS-REFERENCE TO RELATED APPLICATIONS

This application is a continuation of International Patent Application PCT/EP2017/083186, filed on Dec. 18, 2017, which is incorporated herein by reference in its entirety.

### BACKGROUND

### Technological Field

The disclosed technology relates to the field of characterizing materials, and more specifically, to methods and systems for characterizing regions with different crystallinity, for example, defects in crystalline materials.

### Description of the Related Technology

Electron channeling contrast imaging (ECCI) has been demonstrated to be a powerful technique to image single extended crystalline defects, such as dislocations or stacking faults. This technique hence allows determining the density of these crystalline defects in various materials. For this purpose, a focused electron beam is scanned across the sample surface while the intensity of backscattered or forward scattered electrons is mapped, as described by Wilkinson et al., “Electron diffraction based techniques in scanning electron microscopy of bulk materials.” Micron, 28(4), 279-308. The intensity of backscattered or forward scattered electrons depends on the lattice parameter as well as on the orientation of the lattice planes, with respect to the incident electron beam. Crystalline defects cause a local deformation (extending over a few nm) of the lattice planes which leads to a local variation of the backscattered intensity, which can be mapped using a backscatter detector. To spatially resolve single defects, the electron beam needs to be smaller than the spatial extent of the lattice deformation.

In case of lowly defective samples, a rather large area needs to be analyzed by scanning the focused electron beam across, in order to derive statistically relevant information on the defect density. The overall measurement time is then determined by the number of pixels (=scan area/electron beam spot size) as well as the integration time for each pixel and hence can add up to several hours. This hampers the application of electron channeling contrast imaging as a routine analysis tool for defect characterization on lowly defective materials.

There is still a need for good methods and devices for characterizing regions with different crystallinity, for example, defects in crystalline materials. There is still a need for good methods and devices for characterizing epitaxially grown materials.

### SUMMARY OF CERTAIN INVENTIVE ASPECTS

One objective of the disclosed technology is to provide good methods and devices for characterizing regions with different crystallinity.

It is an advantage of some embodiments of the disclosed technology that measurement contributions stem from regions to be characterized and not from the background, thus resulting in a good signal to noise ratio.

It is an advantage of some embodiments of the disclosed technology that accurate characterization of regions inducing deviations in crystalline properties, such as defects in a crystalline material, distortion in lattice planes or other crystalline defects, or confined crystalline structures in a non-crystalline matrix, can be performed.

It is an advantage of some embodiments of the disclosed technology that measurements can be performed with reduced overall measurement time.

It is an advantage of some embodiments of the disclosed technology that measurements with a good sensitivity can be obtained.

It is an advantage of some embodiments of the disclosed technology that a good signal to noise ratio can be obtained even for measurements with a short measurement time.

It is an advantage of some embodiments of the disclosed technology that fast and nondestructive imaging of distributions and density assessment of deviations in various crystalline materials, e.g. defects in crystalline materials, can be obtained.

It is an advantage of some embodiments of the disclosed technology that wafer scale metrology can be obtained with an acceptable wafer throughput, i.e. that full wafer analysis can be obtained in reasonable time.

The above objective is obtained by a method and system according to embodiments of the disclosed technology.

The disclosed technology relates to a method of characterizing a region in a sample under study, the sample under study comprising a first region having first crystalline properties and a second region having second crystalline properties. The method comprises: irradiating the sample under study with an electron beam, the average relative angle between the electron beam and the sample under study being selected so that a contribution in the backscattered and/or forward scattered signal of the first region is distinguishable from a contribution of the second region; detecting the backscattered and/or forward scattered electrons; and deriving a characteristic of the first and/or the second region in the sample under study from the detected backscattered and/or forward scattered electrons. Irradiating the sample under study comprises modulating the instantaneous relative angle α between the electron beam and the sample under study with a predetermined modulation frequency during the irradiation. Detecting the backscattered and/or forward scattered electrons comprises detecting the resulting modulated backscattered or forward scattered electrons signal modulated at the predetermined modulation frequency. The first crystalline properties and the second crystalline properties may be different from each other.

As used herein, a contribution in the backscattered and/or forward scattered signal that is distinguishable from a contribution of the second region means the fact that a detected backscattered and/or forward scattered signal as detected for the first crystalline properties is measurably different from a detected backscattered and/or forward scattered signal as detected for the second crystalline properties. The latter may depend and be adapted to the detectors used.

In some embodiments, the first region may correspond to a region having a deviation in crystalline properties, while a second region being a reference region having reference crystalline properties. In some embodiments, the first region may be a defect or defect region introducing a deviation in crystalline properties. Such defects may be crystalline defects, such as single extended crystalline defects, like dislocations or stacking faults. Then, the reference region is typically a crystalline structure. In these applications, the elements or regions of interest, also referred to as defects, are crystalline defects or positions where crystalline defects occur within the crystalline material.

The first and second regions may also refer to, e.g., a composite material with nanospheres in an amorphous matrix. Thus, in some applications, deviations in a sample under study may refer to situations wherein deviations are present in confined crystalline structures which are themselves embedded in a non-crystalline matrix, one example being fins introduced in a shallow trench isolation matrix. Consequently, it is not required that the sample under study is a full crystalline matrix.

More generally, deviations correspond to elements or regions of interest for which one wants to determine a characteristic such as a density, a composition, or a crystallinity. The remaining part of the sample under study then corresponds to the material wherein the elements or regions of interest are embedded and may be referred to as the matrix wherein the deviations, e.g. defects, are embedded. Such a matrix may be fully or partly crystalline.

It is an advantage of some embodiments of the disclosed technology that by increasing the beam size, a reduced number of pixels needs to be analyzed for a given sample area. It is an advantage of some embodiments of the disclosed technology that by increasing the beam size, a reduced integration time per pixel is required, since there are a larger beam current as well as a larger backscatter signal. It is a further advantage that, by using a relative angle between the electron beam and the sample under study modulated at a given predetermined frequency, detection can be performed with enhanced sensitivity to deviations, since contributions in the angle modulated backscattered or forward scattered electrons signal from deviation free regions will be small or even negligible.

The sample under study and the average beam size may be selected to be larger than the size of the region to be characterized, e.g. the deviation to be characterized.

The detection may be performed using lock-in amplification at the angle modulation frequency. It is an advantage of some embodiments of the disclosed technology that detection at the angle modulation frequency can be easily obtained by implementing a lock-in amplification technique which is easily implementable.

The average relative angle between the electron beam and the sample under study may be such that the channeling condition is fulfilled for the second region, i.e. the reference region. The channeling condition is defined as the angle condition for the relative angle under which a minimal backward or forward scattering electron signal is obtained.

The modulation of the instantaneous relative angle α between the electron beam and the sample under study may be obtained by periodically tilting of the sample. It is an advantage of some embodiments of the disclosed technology that a mechanically easily implementable solution can be used for inducing the modulation of the incidence angle.

The modulation of the instantaneous relative angle α between the electron beam and the sample under study may be obtained by electron beam rocking. It is an advantage of some embodiments of the disclosed technology that techniques for beam rocking can be used for implementing modulation of the incidence angle.

The first regions in the sample under study may be crystalline defects in a crystalline structure, and deriving a characteristic of the first and/or the second region in the sample under study from the detected backscattered and/or forward scattered electrons may comprise determining a density of crystalline defects. It is an advantage of some embodiments of the disclosed technology that a density of crystalline defects such as dislocations or stacking faults can be determined, even if the density is relatively low.

The sample under study may be confined crystalline structures embedded in a non-crystalline matrix, and deriving a characteristic of the first and/or the second region in the sample under study may comprise determining a density of deviations in the confined crystalline structures. It is an advantage of some embodiments of the disclosed technology that detection of deviations in crystalline structures embedded in a non-crystalline matrix can be performed. An example of such crystalline structures may be fins in a shallow trench isolation matrix. It thereby is an advantage that the non-crystalline matrix, e.g. amorphous matrix, does not contribute to the backscattered or forward scattered electron signal. The modulation technique then allows to decouple the contributions from the two materials, thus allowing analysis of deviations in crystalline features smaller than the spot size of the primary electron beam.

The method may comprise obtaining an indication on a density of deviations in crystalline properties, e.g. variations in crystalline properties, and may comprise identifying a region of interest and decreasing the electron beam spot size, e.g. a beam spot diameter, to localize a deviation of crystalline properties.

The disclosed technology further relates to a system of characterizing a region in a sample under study by electron channeling contrast imaging, the sample under study comprising a first region having first crystalline properties and a second region having second crystalline properties. The system comprises a sample holder configured to hold the sample under study; an irradiation system configured to irradiate the sample under study with an electron beam, the sample holder and/or the irradiation system being configured to provide an average relative angle between the electron beam and the sample under study such that a contribution in the backscattered or forward scattered signal of the first region is distinguishable from a contribution of the second region; and a detector configured to detect backscattered or forward scattered electrons upon interaction of the electron beam and the sample under study, wherein the system further comprises a controller to modulate the relative instantaneous angle α between the electron beam and the sample under study with a predetermined modulation frequency during the irradiation, and to control the detector to detect the backscattered or forward scattered electrons at the modulation frequency.

The sample holder and/or the irradiation system may be adjustable in orientation. By altering the orientation of one or more of the sample holder and/or the irradiation system, a different angle between the electron beam and the sample under study in the sample holder can be obtained. The system may comprise means for altering the orientation of the sample holder and/or the orientation of the irradiation system. The sample holder may be adapted for holding the sample under a predetermined orientation with respect to the sample holder.

The system may comprise a lock-in amplifier configured to modulate the relative instantaneous angle between the electron beam and the sample under study and to detect the backscattered or forward scattered electrons at the modulation frequency.

The modulation of the relative instantaneous angle between the electron beam and the sample under study in the sample holder may be performed based on a modulation frequency provided by the controller.

The system may be equipped with a sample tilting means and/or a beam rocking means for inducing a modulation of the instantaneous relative angle α between the electron beam and the sample under study.

The system may further comprise a processor configured to derive a characteristic of a first crystalline region or a second crystalline region in the sample under study based on the detected backscattered or forward scattered electrons.

The irradiation source may be configured to irradiate the sample under study with an electron beam having an average beam size, e.g. average beam diameter, selected to be larger than the size of the region to be characterized, e.g. the deviation. In some embodiments, the average beam diameter may be at least 10 nm on the sample under study. The average beam diameter may be a beam diameter of a disc covering the same area as the area covered by the beam.

The disclosed technology further relates to a system of characterizing a region in a sample under study by electron channeling contrast imaging, the sample under study comprising a first region having first crystalline properties and a second region having second crystalline properties. The system comprises a sample holder configured to hold the sample under study; an irradiation system configured to irradiate the sample under study with an electron beam; a detector configured to detect backscattered or forward scattered electrons upon interaction of the electron beam and the sample under study; and a controller operably connected to the sample holder and/or the irradiation system and to the detector, the controller comprising a memory provided with a program to execute characterizing a region in a sample under study, when run on the controller, by: irradiating the sample under study with an electron beam and modulating, during the irradiation, the instantaneous relative angle α between the electron beam and the sample under study with a predetermined modulation frequency, the average relative angle between the electron beam and the sample under study being selected so that a contribution in the backscattered or forward scattered signal of the first region is distinguishable from a contribution of the second region, detecting the resulting modulated backscattered or forward scattered electrons signal modulated at the predetermined modulation frequency, and deriving a characteristic of the first and/or the second region in the sample under study from the detected backscattered or forward scattered electrons.

The disclosed technology further relates to a controller configured to control a system of characterizing a region in a sample under study by electron channeling contrast imaging, the sample under study comprising a first region having first crystalline properties and a second region having second crystalline properties, the controller being configured to modulate a relative instantaneous angle α between an electron beam and the sample under study with a predetermined modulation frequency during irradiation, and for detecting backscattered or forward scattered electrons at the modulation frequency during detection.

The disclosed technology further relates to a computer program product comprising instructions which, when executed on a processing means, induce a method as described above. The computer program may comprise input and/or output instructions for receiving information from and providing information to a system of characterizing a region in a sample under study by electron channeling contrast imaging.

The computer program product may comprise instructions for generating: control signals for an irradiation system to irradiate the sample under study with an electron beam, the average relative angle between the electron beam and the sample under study being selected so that a contribution in the backscattered and/or forward scattered signal of the first region is distinguishable from a contribution of the second region; instructions for generating control signals for a detection system to detect the backscattered and/or forward scattered electrons; and instructions for generating control signals for a processor to derive a characteristic of the first and/or the second region in the sample under study from the detected backscattered and/or forward scattered electrons. The instructions for generating control signals for an irradiation system may be adapted so that the irradiation comprises modulating the instantaneous relative angle α between the electron beam and the sample under study with a predetermined modulation frequency during the irradiating. The instructions for generating control signals for a detection system may be adapted so that the detection comprises detecting the resulting modulated backscattered or forward scattered electrons signal modulated at the predetermined modulation frequency.

Particular and preferred aspects of the invention are set out in the accompanying independent and dependent claims. Features from the dependent claims may be combined with features of the independent claims and with features of other dependent claims as appropriate and not merely as explicitly set out in the claims.

These and other aspects of the invention will be apparent from and elucidated with reference to the embodiment(s) described hereinafter.

### BRIEF DESCRIPTION OF THE DRAWINGS

FIG. 1 shows (left) an electron beam irradiation a crystalline sample and (right) the backscattered intensity according to the angle between the beam and the crystal planes.

FIG. 2 shows a flowchart of a method according to embodiments of the disclosed technology.

FIG. 3 and FIG. 4 show different schematic embodiments of a system according to embodiments of the disclosed technology.

FIG. 5 shows a large beam irradiating over a large sample area.

Any reference signs in the claims shall not be construed as limiting the scope. In the different drawings, the same reference signs refer to the same or analogous elements.

### DETAILED DESCRIPTION OF CERTAIN ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

As used herein, a first region having first crystalline properties means a region of interest for which properties are to be determined, e.g. defects or confined crystalline structures (which are embedded in a non-crystalline matrix).

As used herein, a second region having second crystalline properties means a region used as a reference region, e.g. a defect-free crystalline region or a non-crystalline matrix at positions wherein the confined crystalline structures are not embedded. As used herein, the instantaneous relative angle α between the beam and the substrate means the angle between the beam and the substrate. As used herein, the average relative angle means the average angle obtained by averaging the instantaneous relative angle α over time (thus averaging out the modulation).

In a first aspect, the disclosed technology relates to a method of characterizing a region in a sample under study. The sample under study comprises a first region having first crystalline properties and a second region having second crystalline properties. The method comprises irradiating the sample under study with an electron beam, the average relative angle between the electron beam and the sample under study being selected so that the contribution in the backscattered or forward scattered signal of the first region is different from a contribution of the second region. In some embodiments, the first region may be a defect region or a defect and the second region may be a defect free region. A defect region or a defect may refer to a deviation typically smaller in size than the surroundings. Defects or defect regions may be crystalline defects, such as single extended crystalline defects, like dislocations or stacking faults. Alternatively, the first and second region could refer to a composite material with nanospheres in an amorphous matrix, or confined crystalline structures embedded in a non-crystalline matrix.

The method further comprises detecting the backscattered and/or forward scattered electrons, and deriving a characteristic of the first or the second region in the sample under study from the detected backscattered or forward scattered electrons. Irradiating the sample under study comprises irradiating with an electron beam and modulating the instantaneous relative angle between the electron beam and the sample under study with a predetermined modulation frequency during the irradiation. Detecting the backscattered and/or forward scattered electrons comprises detecting the backscattered or forward scattered electrons signal modulated at the predetermined frequency.

By way of illustration, embodiments of the present invention not being limited thereto, standard and optional features will further be described with reference to exemplary systems shown in the drawings. In the examples shown, the principle will be explained using a first region being a crystal defect and a second region being a defect free zone. Nevertheless, as indicated above, embodiments are not limited thereto.

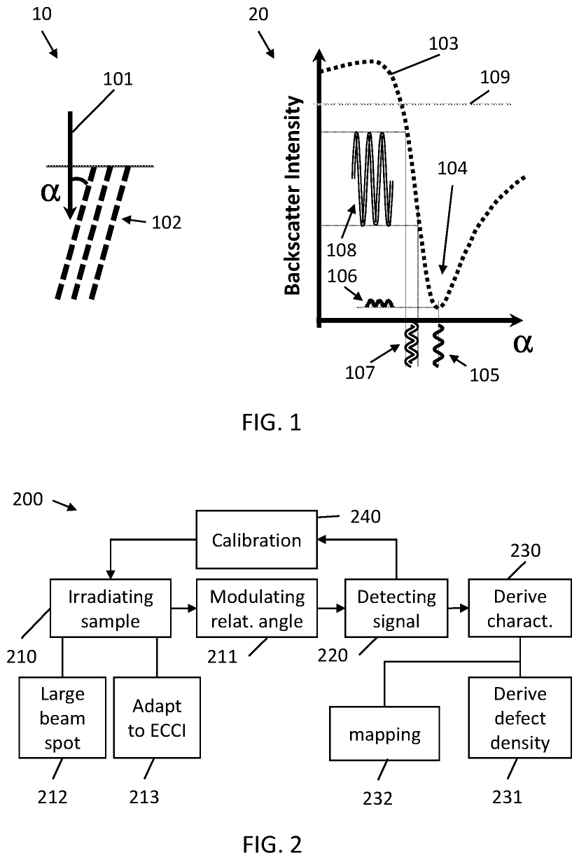

FIG. 1 shows, on the diagram 10 indicated at the left, an electron beam 101 (e.g. a primary electron beam) applied to a sample. The instantaneous angle between the beam 101 and the lattice planes 102 of the sample is the instantaneous relative angle alpha (α). On graph 20 of FIG. 1 shown at the right hand side, the typical backscatter intensity 103 per unit area of scattered electrons is shown as function of the angle α between the electron beam 101 and the lattice planes 102. At angles under the Bragg angle (e.g. between α=0 and higher), the scatter intensity 103 is high, but it drops fast at or near the Bragg position, becoming minimum in the channeling condition 104. When the angle of incidence of the beam is set to the channeling condition 104 for a region corresponding to a defect free region, e.g. in absence of defects, upon periodic modulation 105 of the beam angle, the variation 106 of amplitude will be (near) zero. However, at a defect region, the incident beam is slightly off the channeling condition 105, and upon the same small periodic modulation 107 of the beam angle, a strong modulation 108 of the back-scatter signal takes place.

Embodiments of the disclosed technology may be used with large electron beam spot sizes. The embodiments can be used to detect defects even at low defect density. Normally, the integrated backscatter signal induced by a large electron beam is dominated by electrons back scattered from the sample, for example from the defect free region, even if the sample is oriented in channeling condition. This represents the large background signal 109 of the graph 20, and it is unrelated to the defects. In some embodiments of the disclosed technology, a few defects or even a single defect would give rise to a detectable signal, because the beam angle is set close or at the Bragg condition at the defect site, which causes a strong modulation of the back-scatter signal upon periodic modulation of the beam angle, rather than just a marginal variation in backscatter intensity due to lattice deformation.

When using a large beam spot size, the area of the sample within the electron beam spot will show an increase of the scattered intensity with the number of defects, because the area affected by the defect induced lattice distortion will increase. By detecting the signal at the modulated frequency, a nearly background free signal is obtained, providing enhanced S/N ratio.

FIG. 2 shows, in the flowchart, an exemplary method 200 of characterizing a region in a sample under study with enhanced sensitivity using an electron beam. The method may be an electron scanning back- or forward-scattering microscopy technique, for example within an ECCI framework, etc. The method comprises irradiating 210 a sample with an electron beam under an angle such that the contribution of the scattered signal (either back or forward-scattered) of a first region, for example a region comprising defects can be distinguished from the contribution of a second region, for example a defect-free region. For example, the contribution of the first region may be larger than that of the defect-free region. The method further comprises modulating 211 the instantaneous relative angle α between the incident electron beam and the sample. The latter can in one embodiment be obtained by electron beam rocking, using an alternating magnetic field using coils, e.g. alignment and/or deflection coils, in the alignment column of the analysis device, or by any other suitable means. This solution is easily implementable using existing means, or even by software. In other embodiments, the sample can be periodically tilted using a suitable sample holder, for example. This mechanical solution is easily implementable, for example in adapting existing holders. However, the disclosed technology may use any suitable technique, in order to obtain a modulation of the instantaneous relative angle α between the beam and the sample under study (e.g. between the beam and the lattice planes of the sample) with a predetermined frequency.

The modulation parameters, such as the modulation frequency or amplitude, can be adapted taking into account the type of material of the region used as reference region (i.e. for which channeling conditions are selected) and/or the type of material of the region having deviating crystalline properties and which is to be characterized/analyzed, a scattering factor thereof, a Bragg angle, an inter planar distance, an incidence angle, etc. The modulation frequency, and optionally the amplitude of the modulation, can be predetermined in order to obtain an angular modulation small enough to produce undetectable changes of scatter intensity in a free-defect material at the Bragg condition or near the Bragg condition, but which would produce a detectable modulation in case there is a defect. The method further comprises detecting 220 the signal from the scattered electrons at the predetermined modulation frequency. It is to be noticed that calibration of the modulation parameters may be performed to optimize the modulation. Calibrating 240 the modulation parameters may be performed in a defect-free region of the sample, by for example scanning modulation frequencies and selecting the maximum modulation frequency at which there is no or a minimum detectable change in the scattered signal.

The method further comprises deriving 230, from the detected signal, a characteristic of defects in the sample under study from the detected scattered electrons. Deriving a characteristic of defects may comprise deriving 230 a density of crystalline defects, such as dislocations or stacking faults, which are usually very difficult to observe and analyze. The disclosed technology allows detecting and analyzing (quantitatively and/or by estimation) the density of such defects, even if the density is low. The disclosed technique allows analyzing crystalline structures and defects thereof in confined crystalline structures, for example in locally ordered zones of an amorphous (or short-range ordered) matrix, in crystalline structures embedded in non-crystalline matrices, such as fins in shallow trench isolations, in oxides, etc. In some embodiments of the disclosed technology, the contribution of the matrix to the scattered electron signal does not affect the measured signal. The modulation technique allows to decouple the contributions of the matrix and of the crystalline material, allowing analysis of defects in crystalline features smaller than the spot size of the electron beam. The speed of measurement is also higher.

In some embodiments, the disclosed technology may further comprise mapping the sample, wherein for a detected region corresponding to a deviation, a location is determined. Such mapping may be performed by first obtaining an indication of the density of deviations and identifying a region of interest and thereafter, with decreased electron beam spot size, localizing the deviation.

In some embodiments of the disclosed technology, the method may further comprise selecting 212 a beam diameter (beam spot) larger than the lattice distortion field (e.g. strain field) of the defects under study. This lattice distortion field is usually material and defect-dependent, but traditionally it encompasses several crystalline planes. The exact value can be obtained by simulation, by study using contrast studies such as dark field microscopy, etc. It usually can be well estimated. In some embodiments of the disclosed technology, the spot size is orders of magnitude larger than a nanometer, for example it may be tens of nanometer, or even hundreds of nanometer. In some embodiments, the average beam diameter can be at least 10 nm. A typical scanning electron microscope (SEM) provides spot sizes higher than 1 nm. The method may be applicable to scanning electron microscopy techniques but transmission techniques can also benefit. Using a large beam diameter, e.g. a spot size being larger than the dimension of the region under study, typically may be performed when fast scanning is envisaged whereby an indication of the concentration of regions under study, e.g. defects, is to be obtained. For obtaining an accurate location, typically the beam size is to be reduced. Such mapping/localization is typically performed separately.

In some embodiments of the disclosed technology, a lock-in amplification can be used for signal detection. Because of the strong modulation of the scattered signal of defects under periodic modulation, when using a lock-in amplifier, it is easy to obtain a signal characteristic for the presence of defects based on the amplitude of the backscatter intensity at the modulation frequency. The lock-in amplifier allows to decouple the contributions from a crystal with defects and the rest of the material.

For example, in the case of crystalline structures embedded in non-crystalline matrices, such embodiments allow the analysis of the defects (type, structure, orientation, etc.) in crystalline features smaller than the spot size of the primary electron beam. This decoupling can enhance S/N ratio. For example, it may be applied to confined crystalline structures embedded in a non-crystalline matrix (e.g. fins in shallow trench isolation matrix, nanospheres in an amorphous matrix, etc). A periodic modulation of the beam angle will not affect the backscatter signal originating from the amorphous matrix, but only the backscatter signal coming from the crystalline material. Decoupling of the contributions from the crystalline structures and from the non-crystalline matrix (e.g. amorphous matrix) by using the modulated signal will thus allow the analysis of the defectivity in crystalline features smaller than the spot size of the primary beam, since the contribution of the non-crystalline matrix is filtered out.

Methods according to embodiments of the disclosed technology are especially suitable for performing ECCI. As indicated above, the average relative angle beam sample thereby is selected to obtain channeling condition when measuring on a reference region, i.e. a region showing no deviations, resulting in a minimal scattering (forward or backward) signal contribution from the reference region when detection is performed at the modulation frequency. This results in a significant larger contribution to the scattered signal for regions with deviations, e.g. defects, than the contribution to the scattered signal in regions without deviations, i.e. reference regions such as defect-free regions.

For example, in ECCI, an electron beam can be aligned with the lattice planes of a defect-free region of the material such that channeling condition is fulfilled (e.g. detecting a minimum backscatter intensity). This can be done during the measurement (e.g. as a means for calibration), or before, if the orientation of the crystal is known.

When a large spot size of the primary electron beam is selected 212, the angle between electron beam and lattice planes in regions containing, or nearby, defects will be off-channeling condition, due to defect induced lattice deformation. This leads to an increased backscatter probability. However, a smaller spot size may be used, improving localization analysis of the defects, which may be interesting in study of interlayers, interphases and interfaces, boundaries, etc.

The method may include mapping 232 the sample.

Speed of scanning can be increased, e.g. using a wide spot that allows covering large areas, reducing integration time per pixel due to the larger scattering signal, and reducing the number of pixels required, because the angle orientation of the beam reduces signal from scattering on undistorted (perfectly crystalline) areas, and increases the signal from scattering on strained (defected) areas thanks to the modulation of the incident angle of the beam.

In a second aspect, the disclosed technology relates to a material characterization system, in particular a system suitable to detect and analyze deviations in crystalline properties, such as caused by defects. The system is adapted to characterize a region in a sample under study by electron channeling contrast imaging. Typically, the sample under study comprises a first region having first crystalline properties and a second region having second crystalline properties. The system comprises a sample holder configured to hold the sample under study and an irradiation system configured to irradiate the sample under study with an electron beam. The irradiation system and/or the sample holder are configured to provide an average relative angle between the electron beam and the sample under study such that the contribution in the backscattered and/or forward scattered signal of a first region is distinguishable from a contribution of a second region. The system further comprises a detector configured to detect backscattered and/or forward scattered electrons upon interaction of the electron beam and the sample under study. The system further comprises a controller configured to modulate the instantaneous relative angle α between the electron beam and the sample under study with a predetermined modulation frequency during the irradiation, and to detect the backscattered or forward scattered electrons at the modulation frequency.

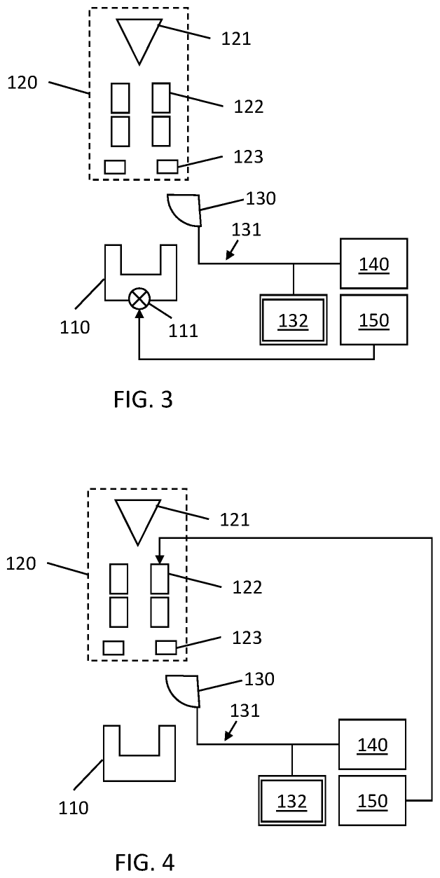

FIG. 3 shows, by way of example, an exemplary system 100. The system comprises a sample holder 110, in order to place a sample. The holder may be a dedicated or a standard holder. For example, a dedicated holder may comprise tilting means 111, such as a piezoelectric actuator, a motor, etc.

The system further comprises an irradiation system 120 for irradiating the sample under study with an electron beam. The system may comprise an electron source 121 such as an emission gun, a cathode, etc.

The irradiation system and/or the sample holder are adapted and configured to provide an average relative angle between the electron beam and the sample under study such that the contribution in the backscattered and/or forward scattered signal of one region, e.g. a defect region, is distinguishable (e.g. larger) than the contribution of another region, such as a defect-free region being used as a reference region. For example, a set of alignment coils 122 can be included, for accurately adjusting the angle of incidence of the beam. The irradiation source may comprise means for aligning the electron beam to an average relative angle of interest (e.g. the channeling angle in an ECCI framework). In alternative embodiments, the holder itself may be configured to provide tilting of the sample, for example orienting the lattice planes of the sample with respect to the incident beam so as to obtain the angle of interest. In further embodiments of the disclosed system, both beam alignment and sample alignment can be provided.

In some embodiments of the disclosed technology, the irradiation source 120 is configured to irradiate the sample under study with an electron beam having an average beam diameter spot size larger than the size of the region to be characterized, i.e. being larger than the region having deviating crystalline properties. In some embodiments, the average beam diameter may be at least 10 nm, when evaluated on the sample under study. For example, for controlling the beam diameter, alignment coils and/or electromagnetic lenses 123 can be used. Accurate detection and analysis of crystalline defects is possible using a wide beam diameter (or spot size), which reduces considerably the analysis time, allowing increasing the backscatter signal due to the larger beam current (and reducing both number of pixels required to map an area, as well as less integration time).

The system further comprises a detector 130 for detecting scattered electrons upon interaction of the electron beam and the sample under stud. For example, the system may comprise a forward scattered detector, or a backscatter detector, or a combination thereof. For example, photodiodes, solid state detectors, e.g. for elastic back-scatter, or any other suitable detector in the art can be used.

The detector 130 may comprise an output 131, for example a recording and/or visualization unit 132. Additionally or alternatively, the output can be sent to a processing unit, e.g. a processor 140, which can be used as an analysis tool. For example, it can be used to derive characteristics of the sample.

The system further comprises a controller 150. This controller enables modulation of the instantaneous relative angle between the electron beam and the sample under study. The modulation can be performed with a predetermined modulation frequency during the irradiating. The system can detect the backscattered and/or forward scattered electrons at the modulation frequency. For example, the processor 140 may be adapted to derive characteristics of defects in the sample, based on the detected electrons in the detector 130 when the angular position of the sample and/or beam is modulated at the frequency set by the controller 150.

The system, e.g. the controller 150, may further comprise means to adjust the modulation parameters, according to the type of sample, target defects, and other experimental circumstances. For example, the controller 150 may be an adjustable analogue controller, or a programmable controller, or a hybrid device.

While in the exemplary embodiment of FIG. 3, the controller induces modulation in the sample itself by controlling the motor 111 of the holder 110, in other embodiment shown in FIG. 4, the controller induces modulation in the irradiation system, e.g. in the alignment coils 122. In other embodiments, the controller may induce and control modulation of the instantaneous relative angle α by controlling both the tilting means 111 and the irradiation system 120.

In some embodiments of the disclosed technology, the controller 150 comprises a lock-in amplifier, improving the decoupling of contributions from a defect in a crystal and the rest of the sample.

According to some embodiments of the disclosed technology, a system 100 of characterizing a region in a sample under study by electron channeling contrast imaging is disclosed, wherein the system comprises a controller operably connected to the sample holder 110 and/or the irradiation system 120 and to the detector 130 and wherein the controller 150 comprising a memory provided with a program to execute characterizing a region in a sample under study, when run on the controller 150, according to a method as described above. In some embodiments, the system therefore is adapted for irradiating the sample under study with an electron beam and modulating, during the irradiating, the instantaneous relative angle α between the electron beam and the sample under study with a predetermined modulation frequency, the average relative angle between the electron beam and the sample under study being selected so that a contribution in the backscattered or forward scattered signal of the first region is distinguishable from a contribution of the second region, detecting the resulting modulated backscattered or forward scattered electrons signal modulated at the predetermined modulation frequency, and deriving a characteristic of the first and/or the second region in the sample under study from the detected backscattered or forward scattered electrons.

In a third aspect of the disclosed technology, a controller for enabling an analysis of a region in a sample according to embodiments of the first aspect is disclosed. The controller may comprise a processor, and it may be integrated with other controllers of a characterization system. The controller allows controlling the modulation of the instantaneous relative angle α between an electron beam and the sample under study with a predetermined modulation frequency during irradiation. The modulation may be performed by modulating the electron beam angle orientation, by modulating the sample angle orientation itself, or by modulating the orientation of both the sample and beam.

The system of the second aspect and the controller may be adapted and automated for performing the method of the first aspect in a programmable way, for example in a program running in a processor. Whereas the following example is explained for a first region being a defect and a second region being a defect-free region, also referred to as reference region, it will be clear that applications with other first regions having a deviation of crystalline properties with respect to second regions having other crystalline properties are also envisaged.

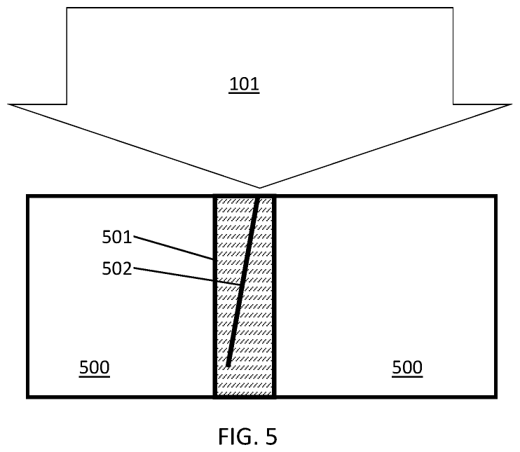

An example of application is shown in FIG. 5, in which an electron beam 101 with a large spot size is applied to a crystalline sample. The sample comprises areas 500 of perfect crystallinity, and strained areas 501, in which the crystal presents deformation due to defects such as the dislocation 502. The electron beam is oriented with respect to the orientation of the perfect crystal such that on average channeling condition is fulfilled for the areas 500 of perfect crystallinity. According to embodiments of the disclosed technology, modulation 105 of the beam angle is applied such that the instantaneous relative angle α changes at a predetermined frequency. When detecting the scatter contribution at the modulation frequency of the relative angle between the beam and the sample, the areas 500 of perfect crystallinity interacting with the large beam do not significantly contribute to the background, whereas the strained areas interacting with the large beam, contribute significantly to the scattered signal, detected at the modulation frequency. In this way, good detection of strained regions can be performed, with a good S/N ratio. Essentially, using a wide beam 101, it thus is possible to detect strained regions with a low or no contribution from electrons scattered from areas 500 without defects, while having a high contribution from electrons scattered from strained areas 501 with defects.

Embodiments of the disclosed technology advantageously results in accurate and fast analysis of defects of semiconductor wafers, which enables wafer scale metrology at high throughput and improves quality control of semiconductor processing.

What is claimed is:

1. A method of characterizing a region in a sample under study, the sample under study comprising a first region having first crystalline properties and a second region having second crystalline properties, the first crystalline properties being different from the second crystalline properties, the method comprising:
irradiating the sample under study with an electron beam, the average relative angle between the electron beam and the sample under study being selected such that a contribution in the backscattered or forward scattered signal of the first region is distinguishable from a contribution of the second region;
detecting the backscattered or forward scattered electrons; and
deriving a characteristic of the first and/or the second region in the sample under study from the detected backscattered or forward scattered electrons,
wherein irradiating the sample under study with an electron beam comprises modulating the instantaneous relative angle between the electron beam and the sample under study with a predetermined modulation frequency, and
wherein detecting the backscattered or forward scattered electrons comprises detecting the backscattered or forward scattered electrons signal modulated at the predetermined modulation frequency.

2. The method according to claim 1, wherein the sample under study and the average beam size are selected to be larger than the size of the region to be characterized.

3. The method according to claim 1, wherein detecting the backscattered or forward scattered electrons is performed using lock-in amplification at the angle modulation frequency.

4. The method according to claim 1, wherein the average relative angle between the electron beam and the sample under study is selected such that the channeling condition is fulfilled for the second region.

5. The method according to claim 1, wherein the modulation of the instantaneous relative angle between the electron beam and the sample under study is obtained by periodic tilting of the sample.

6. The method according to claim 1, wherein the modulation of the instantaneous relative angle between the electron beam and the sample under study is obtained by electron beam rocking.

7. The method according to claim 1, wherein the first regions in the sample under study comprise crystalline defects in a crystalline structure, and wherein deriving a characteristic of the first and/or the second region in the sample under study comprises determining a density of crystalline defects.

8. The method according to claim 1, wherein the sample under study comprises confined crystalline structures embedded in a non-crystalline matrix, and wherein deriving a characteristic of the first and/or the second region in the sample under study comprises determining a density of deviations in the confined crystalline structures.

9. The method according to claim 1, wherein the method further comprises:
obtaining an indication on a density of deviations in crystalline properties;
identifying a region of interest; and
decreasing the electron beam spot size to localize a deviation in crystalline properties.

10. A system of characterizing a region in a sample under study by electron channeling contrast imaging, the sample under study comprising a first region having first crystalline properties and a second region having second crystalline properties, the system comprising:
a sample holder configured to hold the sample under study;
an irradiation system configured to irradiate the sample under study with an electron beam, the sample holder and/or the irradiation system being configured to provide an average relative angle between the electron beam and the sample under study mounted on the sample holder such that a contribution in the backscattered or forward scattered signal of the first region is distinguishable from a contribution of the second region;
a detector configured to detect backscattered or forward scattered electrons upon interaction of the electron beam and the sample under study; and
a controller configured to modulate the instantaneous relative angle between the electron beam and the sample under study with a predetermined modulation frequency during irradiating the sample under study with an electron beam, and to control the detector to detect the backscattered or forward scattered electrons at the modulation frequency.

11. The system according to claim 10, wherein the system further comprises:
a lock-in amplifier configured to modulate the instantaneous relative angle between the electron beam and the sample under study and to detect the backscattered or forward scattered electrons at the modulation frequency, wherein the system is equipped with a sample tilting means and/or a beam rocking means for inducing a modulation of the instantaneous relative angle between the electron beam and the sample under study; and
a processor configured to derive a characteristic of the first region and/or the second region in the sample under study based on the detected backscattered or forward scattered electrons.

12. The system according to claim 10, wherein the irradiation source is further configured to irradiate the sample under study with an electron beam having an average beam size selected to be larger than the size of the region to be characterized.

13. A system of characterizing a region in a sample under study by electron channeling contrast imaging, the sample under study comprising a first region having first crystalline properties and a second region having second crystalline properties, the system comprising:
a sample holder configured to hold the sample under study;
an irradiation system configured to irradiate the sample under study with an electron beam;
a detector configured to detect backscattered or forward scattered electrons upon interaction of the electron beam and the sample under study; and
a controller operably connected to the sample holder and/or the irradiation system and to the detector, the controller comprising a memory provided with a program to execute characterizing a region in a sample under study, when run on the controller, by:
irradiating the sample under study with an electron beam;
modulating, during irradiating the sample under study with an electron beam, the instantaneous relative angle between the electron beam and the sample under study with a predetermined modulation frequency, the average relative angle between the electron beam and the sample under study being selected such that a contribution in the backscattered or forward scattered signal of the first region is distinguishable from a contribution of the second region;
detecting the backscattered or forward scattered electrons signal modulated at the predetermined modulation frequency; and
deriving a characteristic of the first and/or the second region in the sample under study from the detected backscattered or forward scattered electrons.

14. A controller for controlling a system of characterizing a region in a sample under study by electron channeling contrast imaging, the sample under study comprising a first region having first crystalline properties and a second region having second crystalline properties, the controller being configured to modulate the instantaneous relative angle between an electron beam and the sample under study with a predetermined modulation frequency during irradiating the sample under study with an electron beam, and to detect backscattered or forward scattered electrons at the modulation frequency.

15. A computer program product comprising instructions which, when executed on a processor and memory, induce a method according claim 1.

16. The method according to claim 2, wherein detecting the backscattered or forward scattered electrons is performed using lock-in amplification at the angle modulation frequency.

17. The method according to claim 2, wherein the average relative angle between the electron beam and the sample under study is selected such that the channeling condition is fulfilled for the second region.

18. The method according to claim 2, wherein the modulation of the instantaneous relative angle between the electron beam and the sample under study is obtained by periodic tilting of the sample.

19. The method according to claim 2, wherein the modulation of the instantaneous relative angle between the electron beam and the sample under study is obtained by electron beam rocking.

20. The method according to claim 2, wherein the first regions in the sample under study comprise crystalline defects in a crystalline structure, and wherein deriving a characteristic of the first and/or the second region in the sample under study comprises determining a density of crystalline defects.
